(19) United States
(12) Patent Application Publication
(10) Pub. No.: US 2022/0355406 A1
(43) Pub. Date: Nov. 10, 2022

(54) LASER WELDING METHOD, WELDING STRUCTURE, AND BUS BAR MODULE

(71) Applicants: Yazaki Corporation, Tokyo (JP); Toyota Jidosha Kabushiki Kaisha, Toyota-shi (JP)

(72) Inventors: Yuta MATSUNAGA, Shizuoka (JP); Yuki OHIRA, Toyota-shi (JP)

(73) Assignees: Yazaki Corporation, Tokyo (JP); Toyota Jidosha Kabushiki Kaisha, Toyota-shi (JP)

(21) Appl. No.: 17/738,334

(22) Filed: May 6, 2022

(30) Foreign Application Priority Data
May 10, 2021 (JP) 2021-079413

(51) Int. Cl. B23K 1/005; B23K 1/00; H01M 50/516; G01R 19/00; H01M 10/42; H01M 10/48

(52) U.S. Cl. CPC B23K 1/0056; B23K 1/0008; H01M 50/516; G01R 19/0084; H01M 10/425; H01M 10/48; B23K 2101/42

(57) ABSTRACT

There is provided a laser welding method of joining a bus bar and an intermediate member by irradiating a laser beam on a surface of the intermediate member with the bus bar and the intermediate member being overlapped with each other. The laser welding method includes: a first welding step of forming a first welding line by moving the laser beam in a C shape from a welding start point to a welding intermediate point when viewed from a direction orthogonal to a surface of the intermediate member; and a second welding step of forming a second welding line continuous with the first welding line by moving the laser beam from the welding intermediate point to a welding end point located in a welding region formed inside the first welding line from the welding start point and the welding intermediate point.

### CROSS-REFERENCE TO RELATED APPLICATION(S)

The present application claims priority to and incorporates by reference the entire contents of Japanese Patent Application No. 2021-079413 filed in Japan on May 10, 2021.

### BACKGROUND OF THE INVENTION

### 1. Field of the Invention

The present invention relates to a laser welding method, a welding structure, and a bus bar module.

### 2. Description of the Related Art

Conventionally, in a secondary battery mounted in an automobile or the like, an FPC (printed circuit body) has been joined to a metal bus bar by soldering in order to detect the voltage of the secondary battery. In recent years, there has been a technique in which the bus bar is connected with the FPC via an intermediate member. In the technique, an aluminum intermediate member with a plated surface is disposed between the bus bar and the FPC. The intermediate member and the FPC are joined to each other by soldering. The intermediate member and the bus bar is welded by a laser beam.

By the way, the laser welding includes a welding method in which two plate-shaped members to be welded are overlapped with each other and a laser beam is applied to an overlapped portion of the members to be welded. In this case, there is disclosed a method of joining materials to be welded together by laser welding (e.g., see Japanese Patent Application Laid-open No. 2012-125829 and International Publication 2015/186168). In the method, circular welding lines having a different diameter are concentrically set. A laser beam is applied along the welding lines of multiple closed loops while the laser beam is moved.

Metal other than aluminum (e.g., tin and aluminum alloy) contained in a member to be welded, however, may generate an intermetallic compound in a molten portion. Furthermore, metals with different melting points may cause welding defects such as solidification cracking and porosity due to solidification and shrinkage at a welding end point, and there is room for improvement.

### SUMMARY OF THE INVENTION

The present invention has been made in view of the above-described problems, and an object thereof is to provide a laser welding method, a welding structure, and a bus bar module capable of inhibiting welding defects of a joint due to laser welding.

In order to achieve the above mentioned object, a laser welding method, according to one aspect of the present invention, of joining a plate-shaped first member to be welded and a plate-shaped second member to be welded by irradiating a laser beam on a surface of one of the first member and the second member with the first member and second member being overlapped with each other, the method includes a first welding step of forming a first welding line by moving the laser beam in a C shape from a welding start point to a welding intermediate point when viewed from a direction orthogonal to the surfaces of the first member and the second member; and a second welding step of forming a second welding line continuous with the first welding line by moving the laser beam from the welding intermediate point to a welding end point located in a welding region formed inside the first welding line from the welding start point and the welding intermediate point.

According to another aspect of the present invention, in the laser welding method, it is preferable that in the second welding step, the second welding line is formed by moving the laser beam to the welding end point located closer to a side of the welding start point than to a side of the welding intermediate point in the welding region.

In order to achieve the above mentioned object, a welding structure according to still another aspect of the present invention includes a plate-shaped first member to be welded having conductivity; a plate-shaped second member to be welded having conductivity; and a laser welding joint that is formed in an overlapping region where the first member and the second member are overlapped with each other in a thickness direction and that electrically connects the first member with the second member by laser welding joining, wherein in the laser welding joint, when viewed from a direction orthogonal to a surface of the first member, a first welding line is formed in a C shape from a welding start point to a welding intermediate point, and a second welding line continuous with the first welding line is formed from the welding intermediate point to a welding end point located in a welding region formed inside the first welding line from the welding start point and the welding intermediate point.

In order to achieve the above mentioned object, a bus bar module according to still another aspect of the present invention includes a flexible printed circuit body connected to a voltage detector that detects voltage of a battery cell; a plate-shaped intermediate member; a plate-shaped bus bar connected to an electrode terminal of a battery cell constituting a battery module; a solder welding joint that is formed in an overlapping region where the printed circuit body and the intermediate member are overlapped with each other in a thickness direction and that electrically connects the printed circuit body with the intermediate member by solder joining; and a laser welding joint that is formed in an overlapping region where the bus bar and the intermediate member are overlapped with each other in a thickness direction and that electrically connects the bus bar with the intermediate member by laser welding joining, wherein the intermediate member and the bus bar are made of different metal materials, and in the laser welding joint, when viewed from a direction orthogonal to a surface of the intermediate member, a first welding line is formed in a C shape from a welding start point to a welding intermediate point, and a second welding line continuous with the first welding line is formed from the welding intermediate point to a welding end point located in a welding region formed inside the first welding line from the welding start point and the welding intermediate point.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a perspective view of a bus bar module and a battery module according to an embodiment;

FIG. 2 is an exploded perspective view of the bus bar module according to the embodiment;

FIG. 3 is a plan view of a printed circuit body and a bus bar according to the embodiment;

FIG. 4 is a perspective view of the printed circuit body and a joint between the bus bar and an intermediate member according to the embodiment;

FIG. 5 is a plan view of a laser welding joint of the intermediate member according to the embodiment;

FIG. 6 is a plan view of a laser welding joint of an intermediate member according to a variation of the embodiment;

FIG. 7 is a schematic view of a laser welding machine; and

FIG. 8 is a schematic view illustrating a state of molten metal at the time of laser welding.

### DETAILED DESCRIPTION OF THE PREFERRED EMBODIMENTS

An embodiment of a laser welding method, a welding structure, and a bus bar module according to the present invention will be described in detail below with reference to the drawings. Note that the embodiment does not limit the present invention. Furthermore, components in the following embodiment include those that can be easily assumed by a skilled person and those that are substantially the same. Furthermore, the components in the following embodiment can be variously omitted, replaced, and changed without departing from the gist of the present invention.

### Embodiment

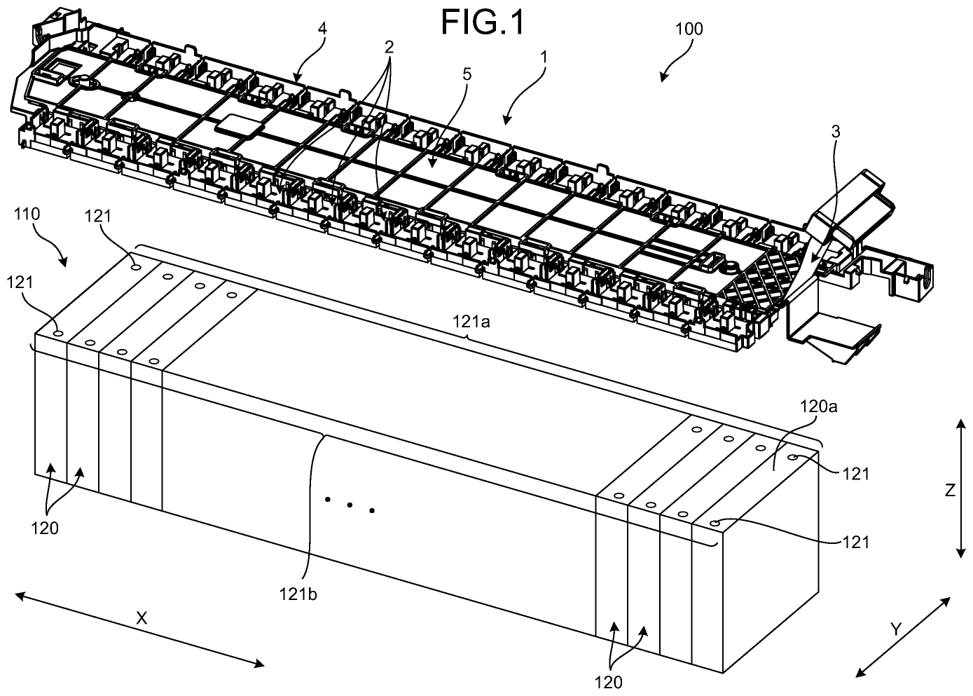

A bus bar module 1 according to the embodiment is incorporated in, for example, a battery pack 100 in FIG. 1. The battery pack 100 includes the bus bar module 1 and a battery module 110. The battery pack 100 is mounted as a power source in a vehicle such as an electric vehicle (EV), a hybrid electric vehicle (HEV), and a plug-in hybrid electric vehicle (PHEV). The battery pack 100 may have a plurality of bus bar modules 1 and a plurality of battery modules 110.

The battery module 110 includes a plurality of battery cells 120. The illustrated battery cell 120 has a rectangular parallelepiped shape. Two electrode terminals 121 are disposed on a first surface 120a of the battery cell 120. The first surface 120a has a substantially rectangular shape.

The plurality of battery cells 120 is arranged along a first direction X. More specifically, the plurality of battery cells 120 is arranged such that a long side of the first surface 120a faces another adjacent long side of the first surface 120a in the first direction X. In the following description, a direction orthogonal to the first direction X in the first surface 120a is referred to as a “second direction Y”. The second direction Y is a longitudinal direction of the first surface 120a. A direction orthogonal to both the first direction X and the second direction Y is referred to as a “third direction Z”. The third direction Z is a height direction of the battery cell 120. The first surface 120a is orthogonal to the third direction Z. For example, the battery pack 100 is mounted in a vehicle such that the first surface 120a faces upward in a vehicle vertical direction.

The two electrode terminals 121 on the first surface 120a are arranged in the second direction Y. One of the two electrode terminals 121 on the first surface 120a is a positive electrode, and the other is a negative electrode. The aggregate of the electrode terminals 121 disposed at one end in the longitudinal direction of the first surface 120a is referred to as a “first electrode group 121a”. Furthermore, the aggregate of the electrode terminals 121 disposed at the other end in the longitudinal direction of the first surface 120a is referred to as a “second electrode group 121b”. In the battery module 110 of the embodiment, positive electrodes and negative electrodes are alternately arranged in the first electrode group 121a. Furthermore, in the second electrode group 121b, positive electrodes and negative electrodes are alternately arranged. The bus bar module 1 of the embodiment connects the plurality of battery cells 120 in series.

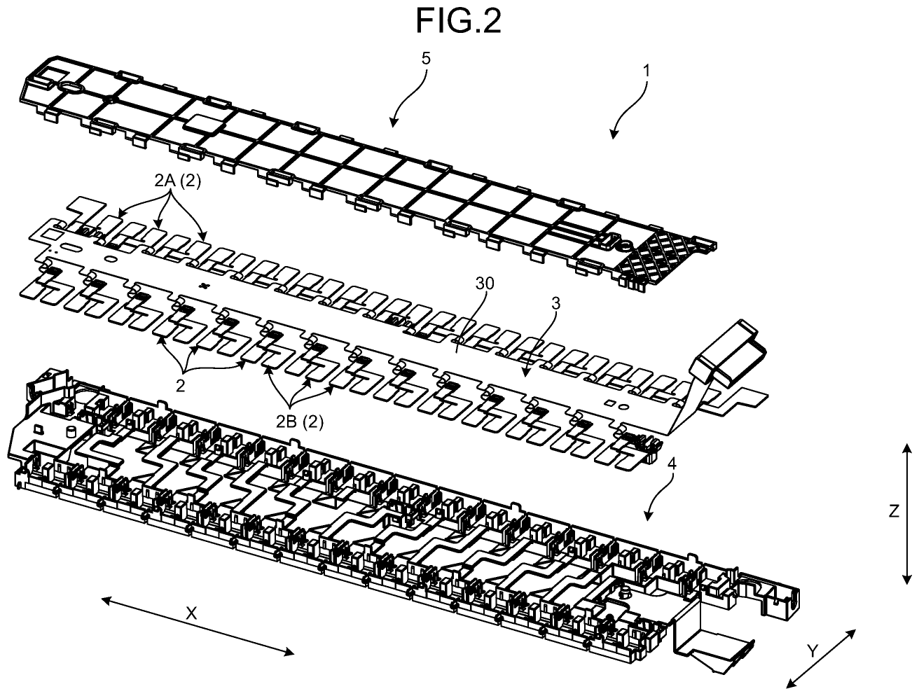

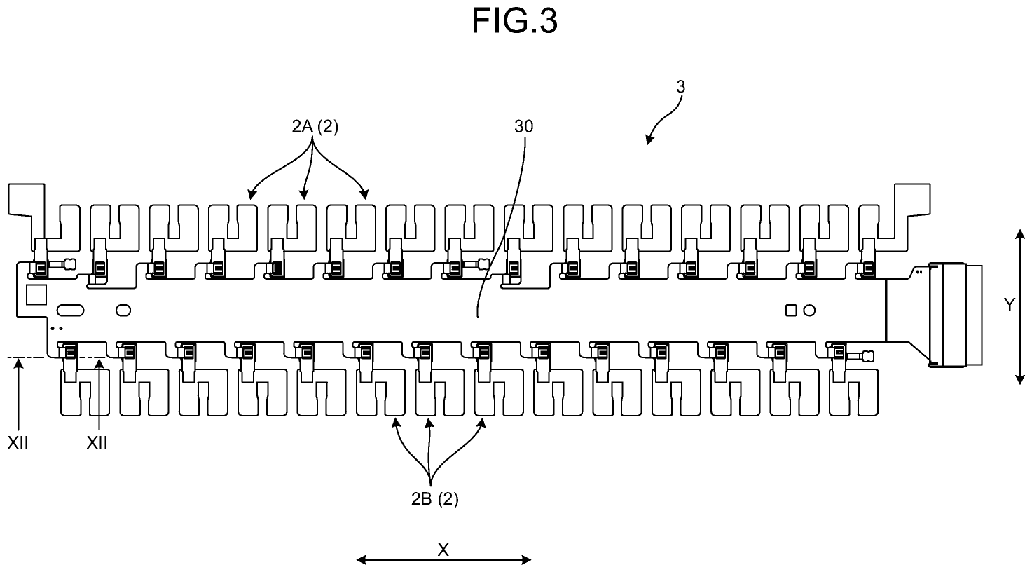

The bus bar module 1 includes a plurality of bus bars 2, a plate-shaped printed circuit body 3, a case 4, and a cover 5. As illustrated in FIGS. 2 and 3, the bus bar module 1 includes a first bus bar group 2A and a second bus bar group 2B. The first bus bar group 2A and the second bus bar group 2B include a plurality of bus bars 2 arranged along the first direction X. The bus bars 2 of the first bus bar group 2A are fixed to the first electrode group 121a of the battery module 110. The bus bars 2 of the second bus bar group 2B are fixed to the second electrode group 121b.

The bus bar 2 is formed of, for example, a conductive metal plate such as copper and aluminum, and is connected to the electrode terminal 121 of the battery cell 120 constituting the battery module 110. The bus bar 2 is one example of a member to be welded.

The printed circuit body 3 is, for example, a flexible printed circuit (FPC), has flexibility, and is connected to a voltage detector (not illustrated) that detects the voltage of the battery cell 120.

An intermediate member 6 is formed of, for example, a conductive metal plate such as aluminum, and plated. The intermediate member 6 is one example of the member to be welded. The intermediate member 6 is obtained by plating the entire plate-shaped aluminum metal member with tin on a nickel base. The intermediate member 6 of the embodiment is preferably formed of a metal material different from that of the bus bar 2. The intermediate member 6, however, may be formed of the same metal material as that of the bus bar 2, and plated with a metal material different from that of the bus bar 2. The intermediate member 6 is interposed between the bus bar 2 and the printed circuit body 3, and physically and electrically connects the bus bar 2 with the printed circuit body 3. The intermediate member 6 extends in an extending direction with the intermediate member 6 being assembled to the bus bar module 1. One end of the intermediate member 6 in the extending direction is joined by soldering to the printed circuit body 3. The other end of the intermediate member 6 is joined by laser welding to the bus bar 2. The intermediate member 6 has a rectangular through hole at an end on the side of the printed circuit body. The intermediate member 6 is disposed such that a chip fuse of the printed circuit body 3 is exposed to the through hole with the printed circuit body 3 and the intermediate member 6 overlapping each other in a thickness direction.

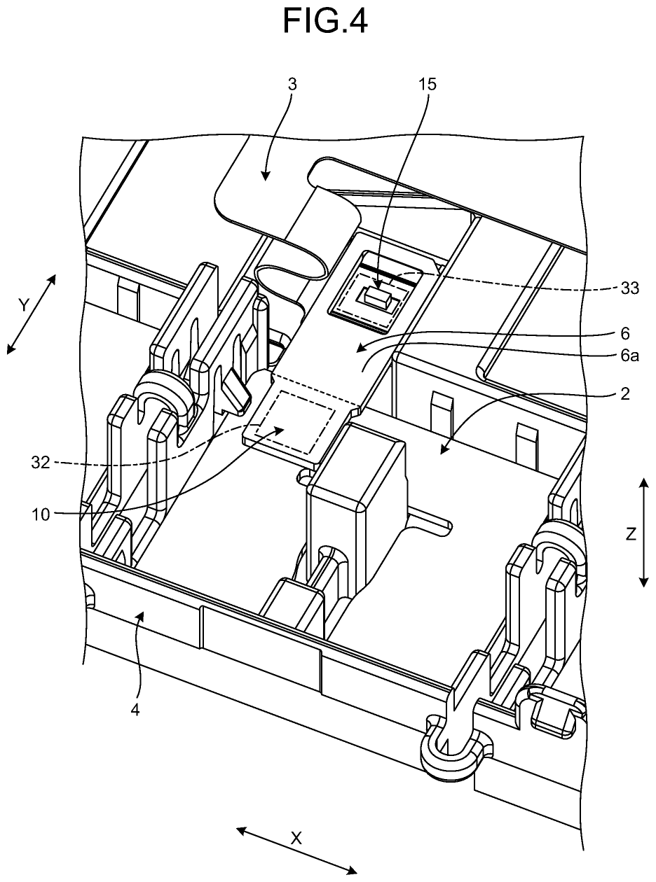

As illustrated in FIGS. 4 to 6, the bus bar module 1 of the embodiment includes a laser welding joint 10. The laser welding joint 10 is formed in an overlapping region 32 where the bus bar 2 and the intermediate member 6 overlap each other in the thickness direction, and electrically connects the bus bar 2 with the intermediate member 6 by laser welding joining. Furthermore, as illustrated in FIG. 4, the bus bar module 1 of the embodiment includes a solder welding joint 15. The solder welding joint 15 is formed in an overlapping region 33 where the printed circuit body 3 and the intermediate member 6 overlap each other in the thickness direction, and electrically connects the printed circuit body 3 with the intermediate member 6 by solder joining. The overlapping region 32 is, for example, an irradiation range of a laser beam LB, and is a welding range by laser welding. The overlapping region 33 is, for example, a soldering range.

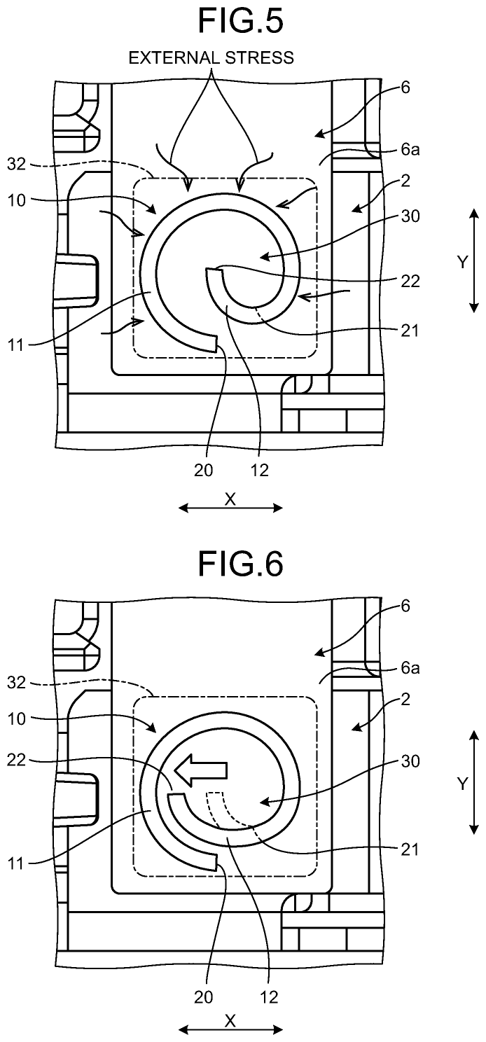

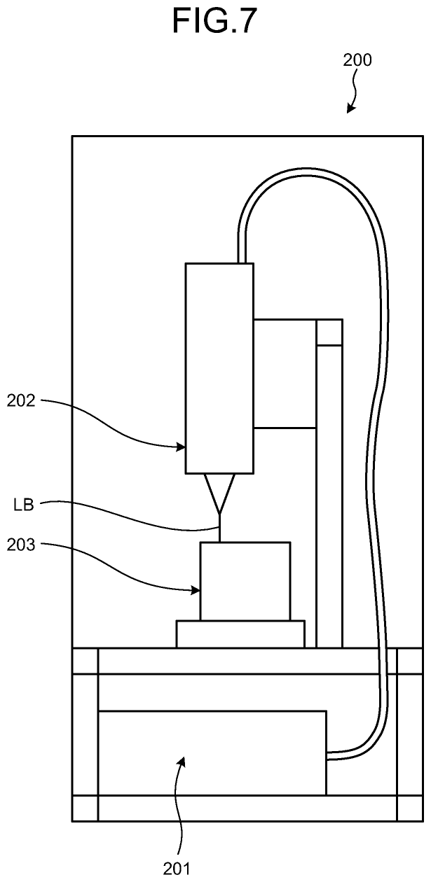

In the laser welding joint 10, when viewed from a direction orthogonal to a surface 6a of the intermediate member 6, a first welding line 11 is formed in a C shape from a welding start point 20 to a welding intermediate point 21. The second welding line 12 continuous with the first welding line 11 is formed from the welding intermediate point 21 to a welding end point 22 located in a welding region 30 formed inside the first welding line 11 from the welding start point 20 and the welding intermediate point 21. Although, in the example in FIG. 5, the welding start point 20 is located on the side of one end in the extending direction of the intermediate member 6 in the overlapping region 32, this is not a limitation. The welding intermediate point 21 is a portion that is on the first welding line 11 and the second welding line 12 continuous with each other and that is bent toward the side of the welding region 30. The welding end point 22 is located, for example, substantially at the center of the C shape formed by the first welding line 11 when viewed from the direction orthogonal to the surface 6a of the intermediate member 6. For example, a laser welding device 200 in FIG. 7 forms the laser welding joint 10.

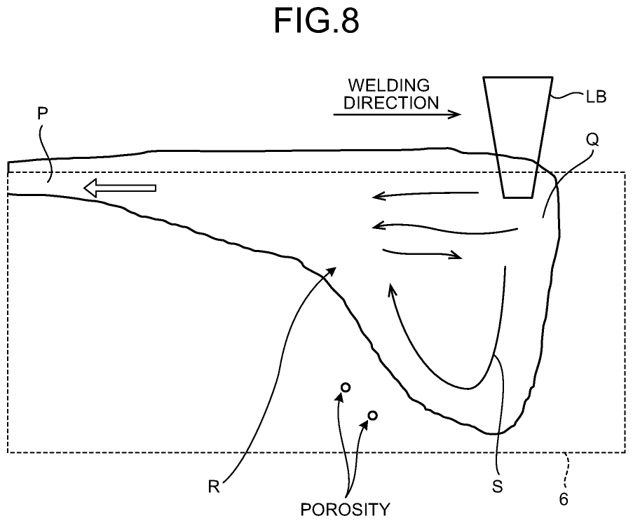

The laser welding device 200 shown in FIG. 7 performs the laser welding method of the embodiment, and irradiates the laser beam LB to one of the two members to be welded to join the two members to be welded. The laser welding device 200 includes a laser oscillator 201, a laser beam irradiator 202, and a mounting table 203. The laser oscillator 201 oscillates a pulsed output at a constant repetition frequency. The laser beam irradiator 202 irradiates the laser beam LB to a member to be welded mounted on the mounting table 203. The optical axis of the laser beam LB applied from the laser beam irradiator 202 is directed to the surface of one of the two members to be welded. In this case, the two members to be welded, that is, the intermediate member 6 and the bus bar 2 are disposed in an overlapped manner. The laser beam LB is applied so as to move on the overlapping region 32, where the intermediate member 6 and the bus bar 2 overlap each other in the thickness direction. The laser beam LB applied to the surface 6a of the intermediate member 6 locally increases the temperature. The temperature that exceeds the melting point of the intermediate member 6 causes a semi-kneaded state in which the intermediate member 6 melts into the bus bar 2 at an appropriate depth in a wedge shape and atoms of both metals are merged and mixed with each other. Moving the laser beam LB in a welding direction increases the temperature at a position Q immediately below the laser beam LB. As illustrated in FIG. 8, a molten pool R has a depth greater than that at a position P, and a molten metal flow S is generated inside the molten pool R. Porosity may occur around the molten pool R. Temperature is low at the position P of the intermediate member 6. Solidification and shrinkage occur in a direction illustrated by an arrow. In this case, replenishment from the molten pool R for solidified and shrunk metal decreases shrinkage strain. As described above, welding is performed by moving the laser beam LB such that welding end point 22 is located in the welding region 30.

The laser welding method includes a first welding step and a second welding step. In the first welding step, as illustrated in FIG. 5, the first welding line 11 is formed by moving the laser beam LB in the C shape from the welding start point 20 to the welding intermediate point 21 when viewed from a direction orthogonal to the surface 6a of the intermediate member 6. In the second welding step, the second welding line 12 continuous with the first welding line 11 is formed by moving the laser beam LB from the welding intermediate point 21 to the welding end point 22, which is located in the welding region 30 formed inside the first welding line 11 from the welding start point 20 and the welding intermediate point 21.

In the laser welding method of the embodiment, the first welding line 11 is formed by moving the laser beam LB in a C shape from the welding start point 20 to the welding intermediate point 21 when viewed from a direction orthogonal to the surface 6a of the intermediate member 6.

The second welding line 12 continuous with the first welding line 11 is formed by moving the laser beam LB from the welding intermediate point 21 to the welding end point 22 located in the welding region 30 formed inside the first welding line 11 from the welding start point 20 and the welding intermediate point 21.

As described above, the laser welding method can mitigate concentration of stress caused by solidification and shrinkage on the welding end point 22 by forming the welding lines (11 and 12) such that the welding end point 22 is located in the welding region 30 whose periphery is welded, as compared with the case where the welding lines are simply formed in a C shape conventionally. Furthermore, the laser welding method can lengthen the welding lines, and inhibit generation and development of a crack at the welding end point 22, as compared with the case where the welding lines (scanning distance) are simply formed in a C shape conventionally. The crack is generated between aluminum crystal grains by shrinkage strain at the time of solidification due to an Al—Ni intermetallic compound formed in an aluminum crystal grain boundary, for example.

Conventionally, in order to inhibit the occurrence of a crack and the like at the welding end point 22, a laser beam output at the welding end point 22 has been lowered and an amount of generated heat has been decreased to reduce the influence of solidification and shrinkage. In this case, the welding lines need some lengths. The lengths of the welding lines can be secured by the above-described method even in a narrow welding range.

The welding structure of the embodiment includes the intermediate member 6, the bus bar 2, and the laser welding joint 10. The laser welding joint 10 is formed in the overlapping region 32 where the intermediate member 6 and the bus bar 2 overlap each other in the thickness direction, and electrically connects the intermediate member 6 with the bus bar 2 by laser welding joining. In the laser welding joint 10, when viewed from a direction orthogonal to the surface 6a of the intermediate member 6, the first welding line 11 is formed in a C shape from the welding start point 20 to the welding intermediate point 21. The second welding line 12 continuous with the first welding line 11 is formed from the welding intermediate point 21 to the welding end point 22 located in the welding region 30 formed inside the first welding line 11 from the welding start point 20 and the welding intermediate point 21. As a result, effects similar to those obtained by the above-described laser welding method can be obtained.

The bus bar module 1 of the embodiment includes the printed circuit body 3, the intermediate member 6, the bus bar 2, the solder welding joint 15, and the laser welding joint 10. The solder welding joint 15 is formed in the overlapping region 33, and electrically connects the printed circuit body 3 with the intermediate member 6 by solder joining. The laser welding joint 10 is formed in the overlapping region 32, and electrically connects the bus bar 2 with the intermediate member 6 by laser welding joining. In the laser welding joint 10, when viewed from a direction orthogonal to the surface 6a of the intermediate member 6, the first welding line 11 is formed in a C shape from the welding start point 20 to the welding intermediate point 21. The second welding line 12 continuous with the first welding line 11 is formed from the welding intermediate point 21 to the welding end point 22 located in the welding region 30 formed inside the first welding line 11 from the welding start point 20 and the welding intermediate point 21. As a result, effects similar to those obtained by the above-described laser welding method can be obtained.

Note that, although the welding end point 22 is located substantially at the center of the C shape formed by the first welding line 11 when viewed from the direction orthogonal to the surface 6a of the intermediate member 6 in the above-described embodiment, this is not a limitation. For example, as illustrated in FIG. 6, the welding end point 22 may be located closer to the side of the welding start point 20 than to the welding intermediate point 21 in the welding region 30. In this case, in the second welding step, the second welding line 12 is formed by moving the laser beam LB to the welding end point 22, which is located closer to the side of the welding start point 20 than to the welding intermediate point 21 in the welding region 30. This can reduce the influence of heat on the welding end point 22.

Furthermore, although the welding end point 22 is located in the welding region 30 in the above-described embodiment, this is not a limitation. The welding end point 22 may be located on the side opposite to the welding start point 20 as long as welding defects do not occur.

Furthermore, although the intermediate member 6 is obtained by plating the entire aluminum metal member with tin on a nickel base in the above-described embodiment, this is not a limitation. The intermediate member 6 may be plated with another metal material.

Furthermore, although the laser welding joining is performed on the surface 6a of the intermediate member 6 with the bus bar 2 and the intermediate member 6 being overlapped with each other in the above-described embodiment, this is not a limitation. The laser welding joining may be performed on the surface of the bus bar 2.

Furthermore, the laser welding method and the welding structure according to the present embodiment in the case of being applied to the bus bar module 1 has been described in the above-described embodiment, this is not a limitation.

According to the laser welding method, the welding structure, and the bus bar module of the present embodiment, effects of inhibiting welding defects of a joint due to laser welding can be obtained.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A laser welding method of joining a plate-shaped first member to be welded and a plate-shaped second member to be welded by irradiating a laser beam on a surface of one of the first member and the second member with the first member and second member being overlapped with each other, the method comprising:
a first welding step of forming a first welding line by moving the laser beam in a C shape from a welding start point to a welding intermediate point when viewed from a direction orthogonal to the surfaces of the first member and the second member; and
a second welding step of forming a second welding line continuous with the first welding line by moving the laser beam from the welding intermediate point to a welding end point located in a welding region formed inside the first welding line from the welding start point and the welding intermediate point.

2. The laser welding method according to claim 1, wherein
in the second welding step, the second welding line is formed by moving the laser beam to the welding end point located closer to a side of the welding start point than to a side of the welding intermediate point in the welding region.

3. A welding structure comprising:
a plate-shaped first member to be welded having conductivity;
a plate-shaped second member to be welded having conductivity; and
a laser welding joint that is formed in an overlapping region where the first member and the second member are overlapped with each other in a thickness direction and that electrically connects the first member with the second member by laser welding joining, wherein
in the laser welding joint, when viewed from a direction orthogonal to a surface of the first member, a first welding line is formed in a C shape from a welding start point to a welding intermediate point, and a second welding line continuous with the first welding line is formed from the welding intermediate point to a welding end point located in a welding region formed inside the first welding line from the welding start point and the welding intermediate point.

4. A bus bar module comprising:
a flexible printed circuit body connected to a voltage detector that detects voltage of a battery cell;
a plate-shaped intermediate member;
a plate-shaped bus bar connected to an electrode terminal of the battery cell constituting a battery module;
a solder welding joint that is formed in an overlapping region where the printed circuit body and the intermediate member are overlapped with each other in a thickness direction and that electrically connects the printed circuit body with the intermediate member by solder joining; and
a laser welding joint that is formed in an overlapping region where the bus bar and the intermediate member are overlapped with each other in a thickness direction and that electrically connects the bus bar with the intermediate member by laser welding joining, wherein
the intermediate member and the bus bar are made of different metal materials, and
in the laser welding joint, when viewed from a direction orthogonal to a surface of the intermediate member, a first welding line is formed in a C shape from a welding start point to a welding intermediate point, and a second welding line continuous with the first welding line is formed from the welding intermediate point to a welding end point located in a welding region formed inside the first welding line from the welding start point and the welding intermediate point.
